(19) United States
(12) Patent Application Publication
(10) Pub. No.: US 2024/0258141 A1
(43) Pub. Date: Aug. 1, 2024

(54) METHODS AND APPARATUS FOR CALIBRATION OF SUBSTRATE PROCESSING CHAMBER PLACEMENT VIA IMAGING

(71) Applicant: Applied Materials, Inc., Santa Clara, CA (US)

(72) Inventors: Zhepeng CONG, San Jose, CA (US); Tao SHENG, Santa Clara, CA (US); Nimrod SMITH, Cupertino, CA (US); Khokan C. PAUL, Cupertino, CA (US); Vinh N. TRAN, San Jose, CA (US); Awse MA'AYA, Santa Clara, CA (US)

(21) Appl. No.: 18/160,274

(22) Filed: Jan. 26, 2023

(51) Int. Cl. H01L 21/67; H01L 21/677; H01L 21/68; H01L 21/687

(52) U.S. Cl. CPC H01L 21/67259; H01L 21/67167; H01L 21/67742; H01L 21/681; H01L 21/68764

(57) ABSTRACT

An apparatus, method, and system for calibrating substrate positioning and placement on a substrate support in a process chamber via imaging. In an embodiment, a calibrating substrate is provided. The calibrating substrate generally includes a top surface having a plurality of first marking features and a at least one edge marking feature configured to be detectable relative to the remaining portions of the top surface of the body by an imaging apparatus.

### BACKGROUND

### Field

The present disclosure relates to semiconductor manufacturing and processing. More particularly, the disclosure relates to a method, apparatus, and system for fabricating devices on a semiconductor substrate. Specifically, embodiments of the present disclosure provide a method, apparatus, and system for calibrating substrate positioning and placement in process chambers via imaging.

### Description of the Related Art

Multi-chamber semiconductor manufacturing systems in which multiple process chambers are integrated are being used in processing of substrates to manufacture semiconductor devices. In a multi-chamber manufacturing system, a substrate may be transported from a substrate load lock chamber to a process chamber with a transport robot for processing. One of the challenges of substrate handling and positioning is the need to locate the center of the substrate with sufficient precision to permit accurate placement of the substrate on a substrate support in the process chamber.

As an example, the substrate support (e.g. susceptor) for holding a substrate in a process chamber generally includes a pocket for which the substrate is placed in. For a given substrate, the pocket on the susceptor into which the substrate fits generally has a diameter only slightly larger than that of the substrate. There is often a very small clearance between the edge of the substrate and the edge of the susceptor pocket. If the substrate has contact with the sidewalls of the pocket, local temperature changes occur, resulting in temperature gradients across the substrate. This can cause non-uniformity in process results.

Often, center positioning and placement of the substrate on the susceptor is established by confirming the center of the substrate and the center of the rotating susceptor coincide. Existing substrate center finding methods typically rely on image processing and detection of the edge of the substrate and/or the gap between the edges of the substrate and the susceptor. The edge of the substrate or the gap is incrementally captured as the substrate and the susceptor are rotated on a pedestal. Using edge shadows and/or reflective methods typically rely on similar principles. A map matrix of the edge positions verses rotation angle is used as an input to algorithms, which determine the mathematical center of the substrate. Due to computational requirements, such approaches can require relatively high image processing power and resources and can be time-consuming. Moreover, such approaches may also have limitations on accuracy. For instance, the light from a light source for imaging the substrate position may have a dispersionary effect causing a distorted image of the substrate edge to be captured. Additional inaccuracies in the image could result from movement of the light detector or substrate. Such inaccurate position readings could thus produce inaccurate results in the determination of the center and orientation of the substrate.

Other attempts, have employed lasers to detect the substrate edge by reflectance or dispersion. These methods are somewhat better at detecting the edges of transparent substrates, but pose significant regulatory and safety concerns as well as being expensive to implement. Moreover, full integration of these systems into processing chambers is challenging and therefore can be quite problematic to adapt, install, and tune.

Therefore, there is a need for an improved method, apparatus, and system for calibrating and placing substrates in a process chamber.

### SUMMARY

Embodiments of the present disclosure provide a method, apparatus, and system for calibrating substrate positioning and placement in process chambers via imaging. In some embodiments, a method for analyzing the placement of a calibrating substrate in a process chamber is provided. The method includes placing a calibrating substrate on a substrate support in a process chamber using a transfer robot. The calibrating substrate includes a plurality of marking features and at least one edge marking feature on a top surface of the calibrating substrate. The plurality of marking features and at least one edge marking feature are configured to be detectable by an imaging apparatus coupled to the process chamber. The method continues with capturing one or more images of the calibrating substrate and the substrate support using the imaging apparatus. The one or more images show the plurality of marking features on the calibrating substrate relative to one or more predefined features on the substrate support with the one or more predefined features disposed at predetermined locations on the substrate support. The one or more images are analyzed to determine a center of the substrate support and a true center of the calibrating substrate.

In other embodiments, a calibrating substrate for use in a process chamber is provided. The calibrating substrate includes a circular body having a top surface and a circumference. A plurality of first marking features are disposed on the top surface of the body, and a at least one edge marking feature is disposed on the top surface of the body along a portion of the circumference. The plurality of first marking features and the at least one edge marking feature are configured to be detectable relative to the remaining portions of the top surface of the body by an imaging apparatus.

In further embodiments, a processing system for analyzing a calibrating substrate in a process chamber is provided. The processing system includes a process chamber having a processing volume and a substrate support disposed in the processing volume. The system also includes a calibrating substrate placed on the substrate support by a transfer robot and an imaging apparatus coupled to the process chamber and connected to a controller. The controller includes instructions that, when executed, causes the imaging apparatus to capture one or more images the calibrating substrate and the substrate support. The one or more images show a plurality of marking features on the calibrating substrate relative to one or more predefined features on the substrate support with the one or more predefined features being disposed at predetermined locations on the substrate support. The controller also includes instructions that, when executed, causes a processor to determine a true center of the calibrating substrate and a center of the substrate support using the one or more images.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

It is to be noted, however, that the appended drawings illustrate only typical embodiments of this disclosure and are therefore not to be considered limiting of its scope, for the disclosure may admit to other equally effective embodiments.

FIG. 1 is a schematic side cross-sectional view of a process chamber, according to certain embodiments of the present disclosure.

FIG. 2A shows a top view of an example calibrating substrate, according to certain embodiments of the present disclosure.

FIG. 2B shows a top view of the calibrating substrate in FIG. 2A disposed on a substrate support, according to certain embodiments of the present disclosure.

FIG. 3 is flow diagram of a method for analyzing a calibrating substrate placed by a transfer robot in the process chamber in FIG. 1, according to certain embodiments of the present disclosure.

FIG. 4 is a schematic side cross-sectional view of a processing system, according to certain embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Reference will now be made in detail to the embodiments, examples of which are illustrated in the accompanying drawings, in which some, but not all embodiments are shown. Indeed, the concepts may be embodied in many different forms and should not be construed as limiting herein; rather, these embodiments are provided so that this disclosure will satisfy applicable legal requirements. Whenever possible, like reference numbers will be used to refer to like components or parts.

The present disclosure generally relate to a substrate processing system, and more particularly to methods, apparatus, and systems to facilitate substrate positioning, setup, and monitoring in process chambers. In semiconductor fabrication, prior to the processing of substrates in processing chambers, the set up process for a process chamber generally includes analyzing the placement of the substrate relative to the substrate support to ensure the positioning of the substrate by the transfer robot is proper and optimal for processing. Proper positioning of the substrate by the transfer robot includes making sure the substrate is centered on the substrate support such that the center of the substrate coincides with the center of the substrate support. The placement of the substrate on the substrate support by the transfer robot may be analyzed by processing images of the substrate and the substrate support captured by a camera coupled to the process chamber. As mentioned above, analyzing the placement and position of the substrate includes determining from the captured images the center of the placed substrate for comparison with the center of the substrate support. If the positioning of the center of the substrate obtained from the captured images is determined to be different from the center of the substrate support holding the substrate, the placement of the substrate by the transfer robot may be adjusted and corrected accordingly.

Embodiments disclosed herein include a calibrating substrate for use during set up of a process chamber. The calibrating substrate may assist in ensuring proper substrate placement by a transfer robot by facilitating substrate center detection and correction during a calibrating operation of the process chamber prior to processing. The calibrating substrate includes a plurality of marking features each with a predetermined and known size and location on the calibrating substrate. The plurality of marking features may be configured to be detectable by the imaging apparatus (e.g. camera) coupled to the process chamber. When the detected plurality of marking features are viewed and analyzed relative to one or more defined features on the substrate support and/or preheat ring in the process chamber also with a known size and location, data regarding the calibrating substrate and substrate support may be obtained for determining, among other things, a position of the center of the placed calibrating substrate, a position of the center of the substrate support holding the calibrating substrate, a rotation angle of the calibrating substrate and substrate support, a reference measure for direct scaling at the substrate level in the captured images, and any offset between the calibrating substrate and the substrate support needing to be corrected.

Typically, processing systems have a centralized transfer chamber mounted on a monolith platform. The transfer chamber is the center of activity for the movement of substrates being processed in the system. One or more process chambers are mounted to the transfer chamber at slit valves through which substrates are passed by a substrate handler, or transfer robot. Access to the transfer chamber from the clean ambient environment is typically through one or more load lock chambers attached at other slit valves. The load lock chambers may open to a very clean room, referred to as the white area, or to an optional substrate handling chamber, typically referred to as a mini-environment.

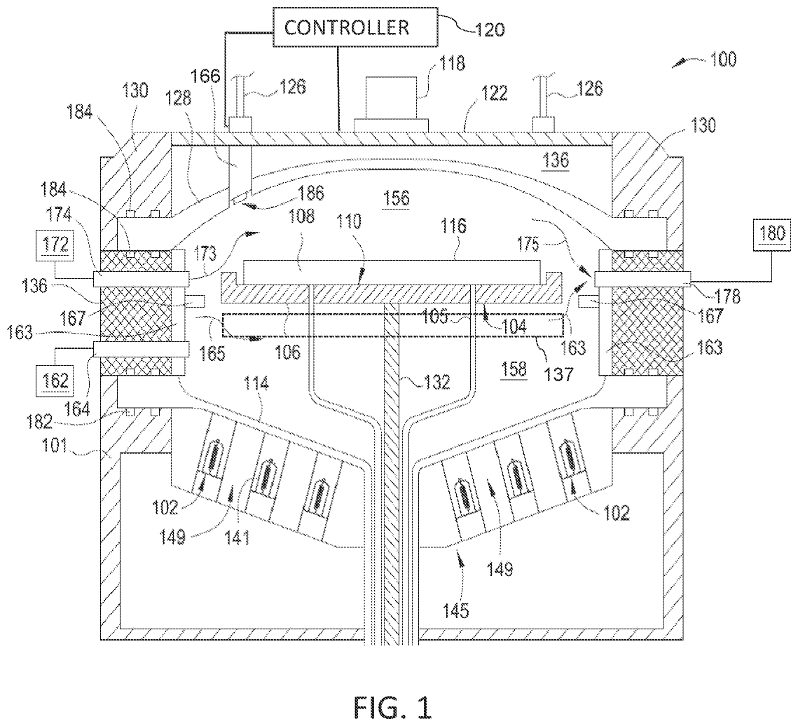

FIG. 1 is a schematic side cross-sectional view of a process chamber 100, according to certain embodiments. The process chamber 100 is a deposition chamber. In one embodiment, which can be combined with other embodiments, the process chamber 100 is an epitaxial deposition chamber. The process chamber 100 is utilized to grow an epitaxial film on a substrate 108. The process chamber 100 creates a cross-flow of precursors across a top surface of the substrate 108.

The process chamber 100 may include an array of radiant heating lamps 102 for heating, among other components, a substrate support 106 (e.g., which may be a susceptor) disposed within the process chamber 100. In some embodiments, the array of radiant heating lamps may be disposed over a window, such as the upper dome 128. The substrate support 106 may be a disk-like substrate support 106 as shown, or may be a ring-like substrate support 107 with no central opening, which supports the substrate from the edge of the substrate to facilitate exposure of the substrate to the thermal radiation of the lamps 102.

As shown, a controller 120 and a camera 166 are in communication with the process chamber 100. The controller 120 may be used to control processes and methods, such as the operations of the methods described herein. The camera 166 may be used to capture images of the substrate 108 and/or components (such as a calibrating substrate) inside the process chamber 100 for use with processes and methods, such as the operations of method 300 described herein. The controller 120, camera 166 and the process chamber 100 can be part of a substrate processing system.

The substrate support 106 is located within the process chamber 100 between an upper window such as the upper dome 128 and a lower window such as a lower dome 114. The upper dome 128, the lower dome 114 and a base ring 136 that is disposed between the upper dome 128 and lower dome 114 generally define an internal region of the process chamber 100. The substrate 108 (not to scale) can be brought into the process chamber 100 and positioned onto the substrate support 106 through a loading port 103. While the upper dome 128 and the lower dome 114 are shown as dome shaped, it is contemplated that planar windows may utilized instead.

The substrate support 106 is shown in an elevated processing position, but may be vertically traversed by an actuator (not shown) to a loading position below the processing position to allow lift pins 105 to contact the lower dome 114, passing through holes in the substrate support 106 and the central shaft 132, and raise the substrate 108 from the substrate support 106. A robot (not shown) may then enter the process chamber 100 to engage and remove the substrate 108 therefrom though the loading port 103. The substrate support 106 then may be actuated up to the processing position to place the substrate 108, with its device side 116 facing up, on a top surface 110 of the substrate support 106.

The substrate support 106, while located in the processing position, divides the internal volume of the process chamber 100 into a process gas region 156 that is above the substrate, and a purge gas region 158 below the substrate support 106. The substrate support 106 is rotated during processing by a central shaft 132 to minimize the effect of thermal and process gas flow spatial anomalies within the process chamber 100 and thus facilitate uniform processing of the substrate 108. The substrate support 106 is supported by the central shaft 132, which moves the substrate 108 in an up and down direction 134 during loading and unloading, and in some instances, processing of the substrate 108. The substrate support 106 may be formed from silicon carbide or graphite coated with silicon carbide to absorb radiant energy from the lamps 102 and conduct the radiant energy to the substrate 108.

In general, the central window portion of the upper dome 128 and the bottom of the lower dome 114 are formed from an optically transparent material such as quartz. “Optically transparent” here means generally transmissive to radiation, but not necessarily 100% transmissive. As will be discussed in more detail below with respect to FIG. 1, the thickness and the degree of curvature of the upper dome 128 may be configured in accordance with the present disclosure to provide a flatter geometry for uniform flow uniformity in the process chamber.

One or more lamps, such as an array of lamps 102, can be disposed adjacent to and beneath the lower dome 114 in a specified manner around the central shaft 132 to independently control the temperature at various regions of the substrate 108 as the process gas passes over, thereby facilitating the deposition of a material onto the upper surface of the substrate 108. While not discussed here in detail, the deposited material may include gallium arsenide, gallium nitride, or aluminum gallium nitride, among other materials.

The lamps 102 may be configured to include bulbs and be configured to heat the substrate 108 to a temperature within a range of about 200 degrees Celsius to about 1600 degrees Celsius. Each lamp 102 is coupled to a power distribution board (not shown) through which power is supplied to each lamp 102. The lamps 102 are positioned within a lamphead 145 which may be cooled during or after processing by, for example, a cooling fluid introduced into channels 149 located between the lamps 102. The lamphead 145 conductively and radiatively cools the lower dome 114 due in part to the close proximity of the lamphead 145 to the lower dome 114. The lamphead 145 may also cool the lamp walls and walls of the reflectors (not shown) around the lamps. Alternatively, the lower dome 114 may be cooled by a convective approach. Depending upon the application, the lampheads 145 may or may not be in contact with the lower dome 114.

A circular shield 167 may be optionally disposed around the substrate support 106 and surrounded by a liner assembly 163. The shield 167 prevents or minimizes leakage of heat/light noise from the lamps 102 to the device side 116 of the substrate 108 while providing a pre-heat zone for the process gases. The shield 167 may be made from CVD SiC, sintered graphite coated with SiC, grown SiC, opaque quartz, coated quartz, or any similar, suitable material that is resistant to chemical breakdown by process and purging gases.

The liner assembly 163 is sized to be nested within or surrounded by an inner circumference of the base ring 136. The liner assembly 163 shields the processing volume (i.e., the process gas region 156 and purge gas region 158) from metallic walls of the process chamber 100. The metallic walls may react with precursors and cause contamination in the processing volume. While the liner assembly 163 is shown as a single body, the liner assembly 163 may include one or more liners with different configurations.

As a result of heating of the substrate 108 by the substrate support 106, the use of an optical pyrometer 118 for temperature measurements/control on the substrate support 106 can be performed. This temperature measurement by the optical pyrometer 118 may also be done on substrate device side 116 having an unknown emissivity since heating the substrate top surface 110 in this manner is emissivity independent. As a result, the optical pyrometer 118 can only sense radiation from the hot substrate 108 that conducts from the substrate support 106, with minimal background radiation from the lamps 102 directly reaching the optical pyrometer 118.

A reflector 122 may be optionally placed outside the upper dome 128 to reflect infrared light that is radiating off the substrate 108 back onto the substrate 108. The reflector 122 may be secured to the upper dome 128 using a clamp ring 130. The reflector 122 can be made of a metal such as aluminum or stainless steel. The efficiency of the reflection can be improved by coating a reflector area with a highly reflective coating such as with gold. The reflector 122 can have one or more conduits 126 connected to a cooling source (not shown). The conduit 126 connects to a passage (not shown) formed on a side of the reflector 122. The passage is configured to carry a flow of a fluid such as water and may run horizontally along the side of the reflector 122 in any desired pattern covering a portion or entire surface of the reflector 122 for cooling the reflector 122.

Process gas supplied from a process gas supply source 172 is introduced into the process gas region 156 through a process gas inlet 174 formed in the sidewall of the base ring 136. The process gas inlet 174 is configured to direct the process gas in a generally radially inward direction. During the film formation process, the substrate support 106 may be located in the processing position, which is adjacent to and at about the same elevation as the process gas inlet 174, allowing the process gas to flow up and round along flow path 173 across the upper surface of the substrate 108 in a laminar flow fashion. The process gas exits the process gas region 156 (along flow path 175) through a gas outlet 178 located on the side of the process chamber 100 opposite the process gas inlet 174. Removal of the process gas through the gas outlet 178 may be facilitated by a vacuum pump 180 coupled thereto. As the process gas inlet 174 and the gas outlet 178 are aligned to each other and disposed approximately at the same elevation, it is believed that such a parallel arrangement, when combing with a flatter upper dome 128 (as will be discussed in detail below), will enable a generally planar, uniform gas flow across the substrate 108. Further radial uniformity may be provided by the rotation of the substrate 108 through the substrate support 106.

The controller 120 includes a central processing unit (CPU), a memory containing instructions, and support circuits for the CPU. The controller 120 controls various items directly, or via other computers and/or controllers. In one or more embodiments, the controller 120 is communicatively coupled to dedicated controllers, and the controller 120 functions as a central controller.

The controller 120 is of any form of a general-purpose computer processor that is used in an industrial setting for controlling various substrate processing chambers and equipment, and sub-processors thereon or therein. The memory, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits of the controller 120 are coupled to the CPU for supporting the CPU (a processor). The support circuits include cache, power supplies, clock circuits, input/output circuitry and subsystems, and the like. Operational parameters (such as a temperature of the substrate 108, a temperature of the substrate support 106, and/or a pressure and/or a temperature for process gas) and operations are stored in the memory as a software routine that is executed or invoked to turn the controller 120 into a specific purpose controller to control the operations of the various chambers/modules described herein. The controller 120 is configured to conduct any of the operations described herein. The instructions stored on the memory, when executed, cause one or more of operations of method 1100 (described below) to be conducted.

The various operations described herein (such as the operations of the method 1100) can be conducted automatically using the controller 120, or can be conducted automatically or manually with certain operations conducted by a user.

The controller 120 is configured to control the camera and rotational positioning in the process chamber 100 by providing an output to controls for the heat sources 141, 143, the gas flow, and the motion assembly 121. The controls include controls for the upper heat sources 141, the lower heat sources 143, the process gas source 151, the purge gas source 162, the motion assembly 121, and the exhaust pump 157.

The controller 120 is configured to adjust the output to the controls based off of sensor readings, a system model, and stored readings and calculations. The controller 120 includes embedded software and a compensation algorithm(s) to calibrate measurements. The controller 120 can include one or more machine learning algorithms and/or artificial intelligence algorithms that estimate optimized parameters for the deposition operations, the purge operations, and/or the cleaning operations. The one or more machine learning algorithms and/or artificial intelligence algorithms can use, for example, a regression model (such as a linear regression model) or a clustering technique to estimate optimized parameters. The algorithm can be unsupervised or supervised.

Substrates (including the calibrating substrate) may be transferred into and out of the internal volume of the process chamber 100 through a transfer door 137 (such as a slit valve). When the transfer door 137 is open, a transfer robot (with a substrate disposed thereon) can extend into the internal volume through the transfer door 137 such that the lift pins 105 can lift the substrate from the transfer robot and land the substrate on the substrate support 106 for processing. After processing, the lift pins 105 can lift the substrate from the substrate support 106 and land the substrate back on the transfer robot, and the transfer robot can be retracted through the open transfer door 137 to remove the substrate from the process chamber 100.

As discussed above, system and methods are provided herein for using a plurality of marking feature disposed on a calibrating substrate to calibrate via image processing the placement and positioning of substrates by the transfer robot in a process chamber. The processing of images of the substrate support and the calibrating substrate thereon may also be used to assist in the detection of the rotation, angle and gap between the edges of the calibrating substrate and the substrate support. As such, a visualization system including an imaging apparatus (e.g., such as a camera 166 shown in FIG. 1), either inside a process chamber (e.g., such as process chamber 100) or outside the chamber but with a view through an aperture in the chamber, may be used to capture images of the calibrating substrate disposed inside the process chamber 100.

The process chamber 100 may include the camera 166 to view the substrate 108, the substrate support 106, and/or a pre-heat ring coupled to the substrate support 106 in process chamber 100. The camera 166 may be positioned above the top of the process chamber 100, and a collection device, for example a light pipe, for the camera may be disposed through the top of the process chamber 100 into the process gas region 156. Alternately, the camera 166 may be positioned inside the process chamber 100. For example, the camera 166 may be disposed in an opening 186 in the upper dome 128 between the upper dome 128 and the reflector 122. The camera 166, or a collection device for the camera, may be disposed through a portal for connecting the conduit 126 to the process chamber 100, or alternatively, the camera 166 may be coupled to the chamber using a chassis. The camera 166 may be capable of operating in a vacuum or at atmospheric pressure. The camera 166 may be in the process chamber 100 to take an image of the substrate 108, an edge ring, a mask, and/or the substrate support 106. The position of the camera 166 relative to the upper dome 128 and the substrate support 106, and the optical characteristics of the camera 166 may be determined to ensure a field of view that includes the regions of interest on the substrate support 106.

The camera 166 can be electrically coupled to the controller 120 that controls operations (e.g., on/off, focusing, image-taking, and the like) of the camera 166. It should be noted that the camera 166 is only one example of an apparatus that can be used for imaging the calibrating substrate and substrate support and that any other types of imaging apparatus can be used as a positioning detection apparatus. In some embodiments, more than one camera can be used to capture images of the substrate support 106. In some embodiments, the camera 166 is an image capturing device which may include a high efficiency, low voltage complementary metal oxide semiconductor (CMOS) sensor, and as such, may function as a single chip video camera. The CMOS sensor may be of the VGA type. The camera 166 may include a lens, such as a wide angle lens or a plano-convex type lens having an appropriate focal length to provide sufficient visual clarity within the desired range of operation of the camera 166. It will be apparent to those skilled in the art that different lenses (e.g., telescoping or rotational prism lenses) may be used for different applications. It will also be appreciated that other types of cameras or optical sensors may be employed, including, but not limited to cameras of the SVGA, XGA, MEGA pixel type, or other image capturing devices. If desired, multiple image capturing devices of differing types of resolution can be employed in conjunction with lenses of varying types and focal lengths. The camera or sensor could be of a static (still) or dynamic (video) type and could be of the charged coupled device (CCD) type. In addition, the camera 166 could be used to output a video signal to any standard TV format.

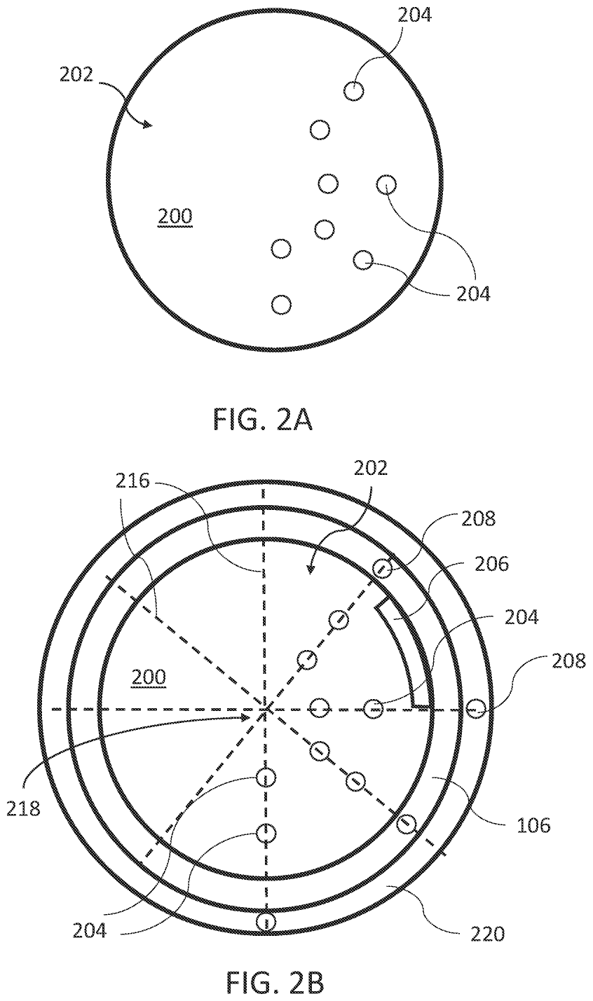

FIG. 2A shows a top view of an example calibrating substrate 200 that may be used in accordance with the methods and operations disclosed herein, according to certain embodiments of the present disclosure. The calibrating substrate 200 may be handled by the transfer robot and placed on the substrate support 106 in the process chamber 100. The calibrating substrate 200 may be formed similar to a device (e.g., wafer, substrate) to be handled by the transfer robot and processed by the process chamber 100. In certain embodiments, the calibrating substrate 200 may include a body having a circular shape and a notch aligner (not shown), in order to properly align the calibrating substrate 200 to an alignment point of the transfer robot. The alignment point may be a corresponding hole or indention on the transfer robot for mating with the notch aligner in the calibrating substrate 200. The notch aligner may assist in providing consistent handling of the calibrating substrate 200 by the transfer robot.

The calibrating substrate 200 includes a top surface 202 having a plurality of marking features 204 formed thereon. The plurality of marking features 204 on the calibrating substrate 200 may assist in calibrating the placement of substrates by the transfer robot. In certain embodiments, the plurality of marking features 204 may assist in determining a position of the center of the calibrating substrate 200 placed by the transfer robot, as well as a position of the center of the substrate support holding the calibrating substrate 200 thereon. The positions of the centers of the calibrating substrate 200 and the substrate support 106 may then be used to determine a calculated offset between the calibrating substrate 200 and the substrate support 106 needing to be corrected. In certain embodiments, the calibrating substrate 200 may also include at least one edge marking feature 206 formed along a circumference of the calibrating substrate 200. The at least one edge marking feature 206 may assist in determining corresponding rotation angles and rotation angle correlations when analyzing captured images of the calibrating substrate 200 inside the process chamber 100.

In some embodiments, which may be combined with other embodiments herein, the plurality of marking features 204 may be of any type of designation capable of being disposed or formed on the top surface 202 of the calibrating substrate 200 and detected by the camera 166 for image analysis. In some embodiments, which may be combined with other embodiments discussed herein, the plurality of marking features 204 may be a surface feature formed on the top surface 202 of the calibrating substrate 200. In other embodiments, the plurality of marking features 204 may be a surface feature etched into the top surface 202 of the calibrating substrate 200. In certain embodiments, the designations for the plurality of marking features 204 may include any number, letter, symbol, shape or pattern, including without limitation, a barcode, a numeric code, an alphanumeric code, a QR code, custom shapes, pattern of shapes, pattern of symbols, series of characters, special characters, and the like. In the example shown in FIG. 2A, the plurality of marking features 204 are formed as circles on and the at least one edge marking feature 206 is formed as a curved arc along a portion of the edge 207 of the calibrating substrate 200.

In order to use the plurality of marking features 204 including the at least one edge marking feature 206 as relative reference points in captured images of the calibrating substrate 200, the plurality of marking features 204 and the at least one edge marking feature 206 may be formed with predetermined dimensions and locations on the top surface 202 of the calibrating substrate 200. By forming the plurality of marking features 204 with known sizes, the plurality of marking features 204 may also be used to provide a reference measure for direct scaling at the substrate level in captured images of the calibrating substrate 200.

FIG. 2B shows a top view of the calibrating substrate from FIG. 2A disposed on the substrate support in the process chamber in FIG. 1, according to certain embodiments. When the calibrating substrate 200 is disposed inside the process chamber 100, images of the plurality of marking features 204 and the at least one edge marking feature 206 on the calibrating substrate 200 may be captured by the camera 166 and analyzed to determine the placement, rotation, and/or positioning of the calibrating substrate 200 relative to the substrate support 106 and/or a preheat ring 220 in the process chamber 100. When images of the calibrating substrate 200 disposed on the substrate support 106 inside the process chamber are obtained, the plurality of marking features 204 in images of the calibrating substrate 200 may be detected and analyzed. Image analysis performed on such images enable the locations of the plurality of marking features 204 to be determined as coordinate points on the top surface 202 of the calibrating substrate 200 relative to one or more predefined features 208 on the substrate support 106 and/or the preheat ring 220 in the process chamber 100. The locations of the plurality of marking feature 204 may then be used to determine a true center of the calibrating substrate 200. Being able to use the plurality of marking features 204 detected in images obtained by the camera 166 may therefore advantageously enables more efficient and accurate determination of a true center of the calibrating substrate 200 via imaging.

Although some examples are described herein as applying the plurality of marking features 204 to the calibrating substrate 200, embodiments of the present disclosure described herein with respect to forming the marking features 204 on the calibrating substrate 200 may be similarly applicable to applying one or more predefined features 208 to the substrate support 106 and/or the pre-heat ring in the process chamber 100. In some embodiments, the one or more predefined features 208 may therefore be formed on the substrates support 106 and/or the preheat ring 220 similar to the formation of the plurality of marking features 204 formed on the calibrating substrate 200 discussed herein. In other embodiments, the one or more predefined features 208 on the substrate support 106 and/or the preheat ring 220 may be implemented digitally after the images of the substrate support 106 and/or the preheat ring 220 are captured by the camera 166.

As shown in FIG. 2B, the one or more predefined features 208 may be formed on a top surface of the substrate support 106 and/or the preheat ring 220. The one or more predefined features 208 may be formed on portions of the substrate support 106 and/or the preheat ring 220 at predetermined locations within the view field of the camera 166. The one or more predefined features 208 captured in images of the calibrating substrate 200 and the plurality of marking features 204 formed thereon may be used as reference points for analyzing the placement and positioning of the calibrating substrate 200 on the substrate support 106. The one or more predefined features 208 on the substrate support 106 and/or the preheat ring 220 in the process chamber 100 may be used to define a coordinate system 212 for determining coordinates of a center 214 of the substrate support 106 and the relative positioning of the calibrating substrate 200 thereon. In certain embodiments where the calibrating substrate 200 is received in a pocket of the substrate support 106, the center 214 of the substrate support 106 may correspond with a center of the pocket of the substrate support 106.

When the calibrating substrate 200 is placed on the substrate support 106, coordinates for each of the plurality of marking features 204 may be determined using the same coordinate system 212 with the one or more predefined features 208 on the substrate support 106 and/or the preheat ring 220 as relative reference points. To assist in determining the position of the center of the calibrating substrate 200 placed on the substrate support 106, the plurality of marking features 204 on the calibrating substrate 200 may comprise a sufficient number of marking features 204 (e.g. at least six marking features 204 representing six coordinate points on the calibrating substrate 200) for determining mathematical representations of at least three chords 216 each extending across the diameter of the calibrating substrate 200. The three chords 216 may then be used to determine coordinates corresponding to a true center 218 of the calibrating substrate 200. The coordinates of the true center 218 of the calibrating substrate 200 may then be compared to the coordinates of the center 214 of the substrate support 106 previously determined to analyze whether the placement of the calibrating substrate 200 on the substrate support 106 by the transfer robot is proper.

Advantageously, the plurality of marking features 204 on the calibrating substrate 200 and the one or more predefined features 208 on the substrate support 106 and/or the preheat ring 220 enables coordinates for the true center 218 of the calibrating substrate 200 and the center 214 of the substrate support 106 to be determined by analyzing stationary images of the calibrating substrate 200 captured by the camera 166 as opposed to rotating images as required when relying on gap detection. Without needing to analyze a series of images of the calibrating substrate 200 being rotated by the substrate support 106, this reduces the need for burdensome image processing that may also require additional corresponding data regarding rotation angles and correlations for the respective rotating images.

In certain embodiments, the at least one edge marking feature 206 includes an arc design formed along a portion of the edge 207 of the calibrating substrate 200. The arc design along the edge 207 of the calibrating substrate 200 may be used to determine via imaging analysis rotation angles of the calibrating substrate 200 and substrate support 106 as well as correlations between the rotation angles of the calibrating substrate 200 and substrate support 106 and a home angle. Images of the at least one edge marking feature 206 on the calibrating substrate 200 may therefore be used to assist in monitoring the positioning of the calibrating substrate 200 as the calibrating substrate 200 is rotated to confirm the calculated offset between the calibrating substrate 200 and the substrate support 106. For example, the at least one edge marking feature 206 on the calibrating substrate 200 may be used to monitor a gap offset via imaging as the calibrating substrate is rotated.

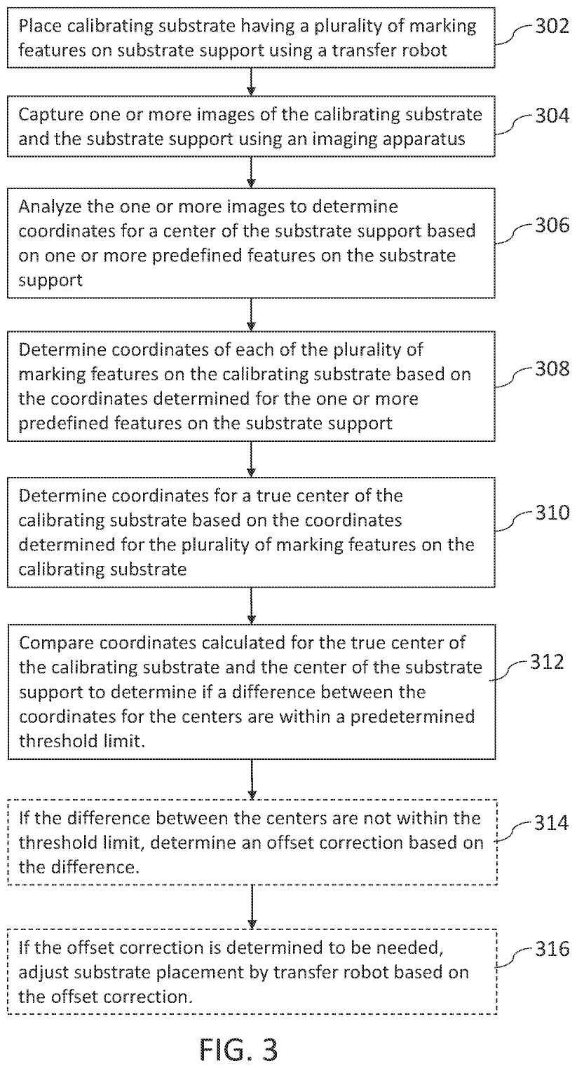

FIG. 3 illustrates a flow diagram of a method 300 for determining an offset of a calibrating substrate placed by a transfer robot on a substrate support in a process chamber, according to certain embodiments of the present disclosure. The method 300 may be executed as a software routine by the controller 120 in a substrate processing system. The method 300 is used to determine and compare coordinates of the true center 218 of the calibrating substrate 200 and the center 214 of the substrate support 106.

The method 300 begins at operation 302 with the calibrating substrate 200 being placed by a transfer robot on a substrate support in a process chamber, such as substrate support 106 in process chamber 100. When the calibrating substrate 200 is disposed on the substrate support 106, at least some of the plurality of marking features 204 on the calibrating substrate 200 and at least some of the one or more predefined features 208 on the substrate support 106 may be within a view field of the camera 166.

At operation 304, one or more images of the calibrating substrate 200 and the substrate support 106 are captured by the camera 166. The one or more images show the position of the plurality of marking features 204 on the calibrating substrate 200 relative to the substrate support 106. In some embodiments, all of the marking features 204 on the calibrating substrate 200 may be within the view field of the camera 166 and may be captured in a single stationary image. In other embodiments, the plurality of marking features 204 may be formed such that only some of the plurality of marking features 204 may be within the view field of the camera 166 at any one time. In such instances, the camera 166 may be moved and/or adjusted to capture additional images of specific portions of the calibrating substrate 200 to image any remaining marking features 204 of the plurality of marking features 204 formed on the calibrating substrate 200. Alternatively, the calibrating substrate 200 may be rotated by the substrate support 106 to move specific portions of the calibrating substrate 200 bearing the remaining features of the plurality of marking features 204 within the view field of the camera 166 for imaging.

In certain embodiments, images of the substrate support 106 include the one or more predefined features 208 formed on the top surface of the substrate support 106 at known locations. Alternatively, the one or more predefined features 208 may be implemented digitally for image analysis after the one or more images are obtained by the camera 166. In both instances, the one or more images may include showing the position of the plurality of marking features 204 relative to the one or more predefined features 208 on the substrate support 106.

In operation 306, the one or more images captured by the camera 166 may be analyzed to determine coordinates for the center 214 of the substrate support holding the calibrating substrate 200 based on the one or more predefined features 208 on the substrate support 106. The one or more predefined features 208 on the substrate support 106 may be used to define a coordinate system such that the known position of the one or more predefined features 208 is used as a reference point from which all other positioning coordinate are defined. In some embodiments, standardized center-finder software algorithms, for example, a best fits center finder routine, may be used to determine the center of the substrate support 106 based on the known coordinates of the one or more predefined features 208 on the substrate support 106.

In operation 308, coordinates for the plurality of marking features 204 depicted in the one or more images are determined based on the coordinates of the one or more predefined features 208 used in operation 306. As mentioned above, the one or more predefined features 208 may be used as reference points for defining a coordinate system. The same coordinate system may extend across the top surface of the substrate support 106 such that the coordinate system may be overlaid over the calibrating substrate 200 disposed on the top surface of the substrate support 106. Coordinates for each of the plurality of marking features 204 on the same coordinate system may then be determined based on the known coordinates of the one or more predefined features 208 and the position of each of the plurality of marking features 204 relative to the predetermined features 208 depicted in the one or more images captured by the camera 166 and detected by image analysis.

In operation 310, coordinates for the true center 218 of the calibrating substrate 200 is determined based on the coordinates of the plurality of marking features 204. The same or similar standardized center-finder software algorithms used for determining coordinates for the center 214 of the substrate support 106 may be used to determine coordinates for the true center 218 of the calibrating substrate 200, based on the coordinates of the plurality of marking features 204 obtained, as described above in operation 306. For example, the coordinates of the plurality of marking features 204 on the calibrating substrate 200 may be used to create mathematical representations of at least three chords extending across the diameter of the calibrating substrate 200, as shown in FIG. 1B. Perpendiculars to the chords may then be checked to determine crossing points of the chords, and from the crossing points, coordinates for the true center 218 of the calibrating substrate 200 may be calculated. Thus, the plurality of marking features 204 on the calibrating substrate 200 may be analyzed and the true center 217 of the calibrating substrate 200 determined.

In operation 312, the coordinates of the true center 218 calculated from operation 310 may be compared to the coordinates for the center 214 of the substrate support 106 to determine if the coordinates of the two centers are within a predetermined threshold limit of one another. If the calculated coordinates of the centers of the calibrating substrate 200 and substrate support 106 are within the threshold limit, then the placement of the calibrating substrate 200 on the substrate support 106 may be considered proper and/or at least sufficient for the processing of substrates to be performed in process chamber 100. In operation 314, if the coordinates of the centers of the calibrating substrate 200 and substrate support 106 are outside the threshold limit, an offset correction is determined based on the difference.

At operation 316, if the offset correction is determined to be needed, the placement of substrates (including the calibrating substrate 200 in operation 302) by the transfer robot may be adjusted based on the offset correction determined by the controller 120 (to center the placement of substrates on the substrate support 106 by the transfer robot). For example, the offset correction may be transmitted to the transfer robot, which may then adjust the programmed substrate handling and placement position by an amount equal to the offset correction.

If adjustments to the transfer robot are made using the calculated offset correction, operations 302-310 may be repeated to confirm the adjustments made using the calculated offset correction are sufficient such that the calculated true center 218 of the calibrating substrate 200 placed by the transfer robot is within the threshold limit of the center 214 of the substrate support 106. Once the placement of the calibrating substrate 200 by the transfer robot is satisfactorily calibrated, the calibrating substrate 200 may be stored in a load lock chamber of a processing system. The method 300 for calibrating substrate placement by the transfer robot may be performed periodically for maintenance and quality control. In some embodiments, the calibration process may be performed more often depending on the extent of the usage of the process chamber 100 and whether changes are made with respect to processing parameters of the process chamber 100 or the substrate being handled by the transfer robot for processing.

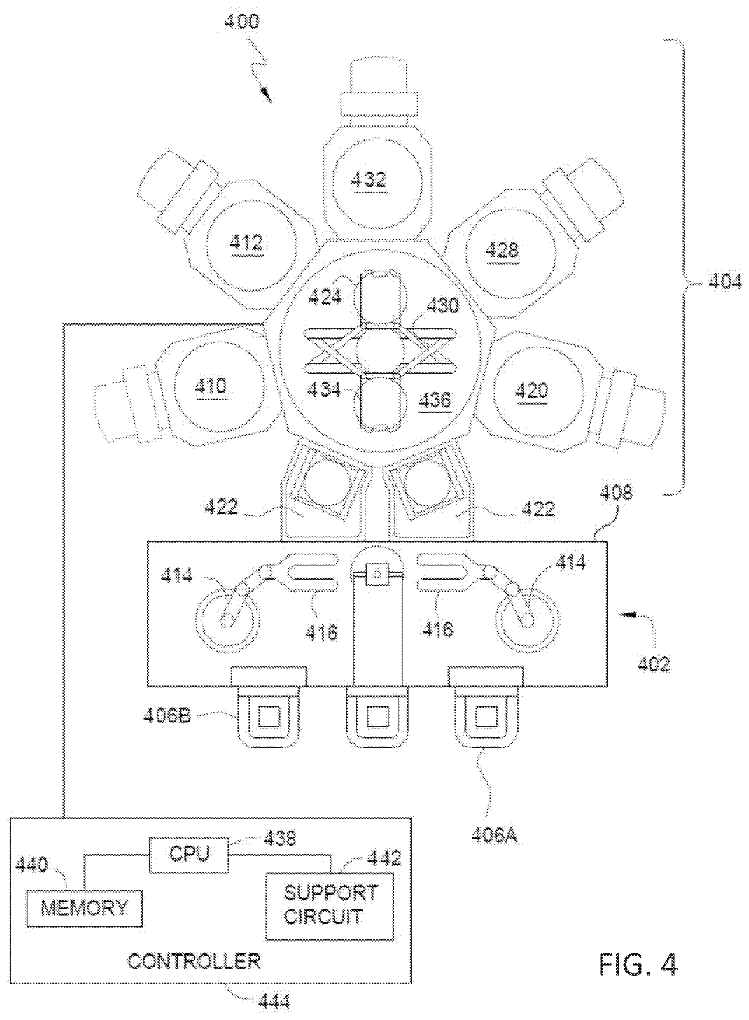

FIG. 4 is a schematic diagram top plan view of a processing system 400, according to one implementation. The processing system 400 includes one or more substrate load lock chambers 422, a vacuum-tight processing platform 404, a factory interface 402, and a controller 444. The substrate load lock chambers 422 may be load lock chambers. In one embodiment, the processing system 400 may be a CENTURA® integrated processing system, commercially available from Applied Materials, Inc., located in Santa Clara, California. It is contemplated that other processing systems (including those from other manufacturers) may be adapted to benefit from the disclosure.

The platform 404 includes a plurality of processing chambers 410, 412, 428, 420, 432 and the one or more substrate load lock chambers 422 that are coupled to a vacuum substrate transfer chamber 436. One or more of the processing chambers 410, 412, 428, 420, 432 in processing system 400 may include process chamber 100. The factory interface 402 is coupled to the transfer chamber 436 through two substrate load lock chambers 422.

In one or more embodiments, the factory interface 402 includes at least one docking station 408 and at least one factory interface robot 414 to facilitate the transfer of substrates. The docking station 408 is configured to accept one or more front opening unified pods (FOUPs). Two FOUPS 406A, 406B are shown in the implementation of FIG. 4. The factory interface robot 414 having a blade 416 disposed on one end of the robot 414 is configured to transfer one or more substrates from the FOUPS 406A, 406B, through the substrate load lock chambers 422, to the processing platform 404 for processing. In certain embodiments, substrates being transferred may be stored in the substrate load lock chambers 422. In certain embodiments, the calibrating substrate 200 may also be stored in one of the substrate load lock chambers 422.

Each of the substrate load lock chambers 422 has a first port interfacing with the factory interface 402 and a second port interfacing with the transfer chamber 436. The substrate load lock chambers 422 are coupled to a pressure control system (not shown) which pumps down and vents the substrate load lock chambers 422 to facilitate passing the substrates between the vacuum environment of the transfer chamber 436 and a substantially ambient (e.g., atmospheric) environment of the factory interface 402.

The transfer chamber 436 has a transfer robot 430 disposed therein. The transfer robot 430 has a blade 434 capable of transferring the substrates, including the calibrating substrate 200, between the substrate load lock chambers 422 and the processing chambers 410, 412, 432, 428, 420.

The controller 444 is coupled to the processing system 400. The controller 444 controls the operations of the system 400 using a direct control of the process chambers 410, 412, 432, 428, 420 of the system 400 or alternatively, by controlling the computers (or controllers) associated with the process chambers 410, 412, 428, 420, 432 and the system 400. In operation, the controller 444 enables data collection and feedback from the respective chambers and controller 444 to optimize performance of the system 400.

The controller 444 is used to control processes and methods, such as the operations of the methods described herein (for example the operations of the method 300 described above). The controller 444 includes a central processing unit (CPU) 438, a memory 440 containing instructions, and support circuits 442 for the CPU. The controller 444 controls various items directly, or via other computers and/or controllers. In one or more embodiments, the controller 444 is communicatively coupled to dedicated controllers, and the controller 444 functions as a central controller.

The controller 444 is of any form of a general-purpose computer processor that is used in an industrial setting for controlling various substrate processing chambers and equipment, and sub-processors thereon or therein. The memory 440, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 442 of the controller 444 are coupled to the CPU 438 for supporting the CPU 438 (a processor). The support circuits 442 can include cache, power supplies, clock circuits, input/output circuitry and subsystems, and the like. Operational parameters (such as UV light power, inert gas temperature, inert gas pressure, native oxide content, particle concentration, and/or atomic particle concentration) and operations are stored in the memory 440 as software routine(s) that are executed or invoked to turn the controller 444 into a specific purpose controller to control the operations of the various systems/chambers/units/modules described herein. The software routine(s), when executed by the CPU 438, transform the CPU 438 into a specific purpose computer. The software routines may also be stored and/or executed by a second controller (not shown) that is located remotely from the system 400.

The controller 444 is configured to conduct any of the operations described herein. The instructions stored on the memory, when executed, cause one or more of operations of method 300 (described above) to be conducted. The various operations described herein can be conducted automatically using the controller 444, or can be conducted automatically and/or manually with certain operations conducted by a user.

The controller 444 is configured to adjust output to controls of the system 400 based off of sensor readings, a system model, and stored readings and calculations. As an example, one or more operating parameters can be measured by one or more sensors positioned along the system 400. The controller 444 includes embedded software and a compensation algorithm to calibrate measurements. The controller 444 can include one or more machine learning algorithms and/or artificial intelligence algorithms that estimate optimized parameters for deposition operation(s), cleaning operations, etching operations, and/or atomic radical treatment operation(s). The one or more machine learning algorithms and/or artificial intelligence algorithms can use, for example, a regression model (such as a linear regression model) or a clustering technique to estimate optimized parameters. The algorithm can be unsupervised or supervised. The one or more machine learning algorithms and/or artificial intelligence algorithms can optimize the operating parameters used in relation to operations described herein.

Embodiments of the disclosure have been described above with reference to specific embodiments and numerous specific details are set forth to provide a more thorough understanding of the disclosure. Persons skilled in the art, however, will understand that various modifications and changes may be made thereto without departing from the broader spirit and scope of the disclosure. The foregoing description and drawings are, accordingly, to be regarded in an illustrative rather than a restrictive sense.

While the foregoing is directed to embodiments of the present disclosure, other and further embodiments may be devised without departing from the basic scope thereof, and the scope thereof is determined by the claims that follow.

What is claimed is:

1. A method for calibrating substrate placement in a process chamber, comprising:
placing a calibrating substrate using a transfer robot on a substrate support disposed in a process chamber, wherein the calibrating substrate comprises a plurality of marking features and at least one edge marking feature on a top surface of the calibrating substrate, wherein the plurality of marking features and the at least one edge marking feature are configured to be detectable by an imaging apparatus coupled to the process chamber, and wherein the at least one edge marking feature is disposed along a circumference of the calibrating substrate;
capturing one or more images of the calibrating substrate and the substrate support using the imaging apparatus;
determining from the one or more images a center of the substrate support using one or more predefined features disposed at predetermined locations on the substrate support; and
determining from the one or more images a true center of the calibrating substrate using the plurality of marking features on the calibrating substrate and the predetermined locations of the one or more predefined features on the substrate support.

2. The method of claim 1, further comprising comparing the center of the substrate support to the true center of the calibrating substrate and confirming whether the center of the substrate support and the true center of the calibrating substrate are within a predetermined threshold limit to determine if an offset correction is needed.

3. The method of claim 2, further comprising adjusting the transfer robot based on the offset correction if the offset correction is determined to be needed.

4. The method of claim 2, further comprising confirming the offset correction when the offset correction is determined to be needed by rotating the calibrating substrate and monitoring a gap offset via imaging using the at least one edge marking feature as the calibrating substrate is rotated.

5. The method of claim 1, wherein determining the true center of the calibrating substrate from the one or more images comprises determining from the one or more images a position of each of the plurality of marking features on the calibrating substrate using the predetermined locations of the one or more predefined features.

6. The method of claim 5, wherein determining the true center of the calibrating substrate further comprises:
determining mathematical representations of at least three chords extending across a diameter of the calibrating substrate using the position of each of the plurality of marking features;
determining a crossing point of the at least three chords; and
determining the true center of the calibrating substrate using the crossing point.

7. The method of claim 1, wherein capturing one or more images of the calibrating substrate and the substrate support comprises capturing one or more images of the one or more predefined features formed on a top surface of the substrate support.

8. The method of claim 1, further comprising digitally implementing in the one or more images the one or more predefined features on the substrate support.

9. The method of claim 1, further comprising analyzing the one or more images from the imaging apparatus to determine a rotation angle of the calibrating substrate using the at least one edge marking feature.

10. A calibrating substrate for use in a process chamber, comprising:
a circular body having a top surface and a circumference;
a plurality of first marking features disposed on the top surface of the body; and
at least one edge marking feature disposed on the top surface of the body and along the circumference of the calibrating substrate;
wherein the plurality of first marking features and the at least one edge marking feature are configured to be detectable relative to the remaining portions of the top surface of the body by an imaging apparatus.

11. The calibrating substrate of claim 10, wherein the plurality of first marking features comprises at least six first marking features positioned for determining mathematical representations of at least three chords each extending across a diameter of the body.

12. The calibrating substrate of claim 10, wherein the plurality of first marking features and the at least one edge marking feature comprise known dimensions extending along the top surface of the body, the known dimensions providing direct scaling to the calibrating substrate and substrate support in images of the calibrating substrate and substrate support.

13. The calibrating substrate of claim 10, wherein the at least one edge marking feature provides a reference point for determination of a rotation angle of the calibrating substrate via imaging.

14. The calibrating substrate of claim 10, wherein the plurality of first marking features and the at least one edge marking feature comprise a surface feature formed on or etched into the top surface of the body.

15. The calibrating substrate of claim 10, wherein the plurality of first marking features comprise a designation, shape, or pattern, including without limitation, a custom shapes, a pattern of shapes, symbols, and special characters.

16. A processing system for analyzing a calibrating substrate in a process chamber, comprising:
a process chamber having a processing volume;
a substrate support disposed in the processing volume, the substrate support configured to receive a substrate;
a calibrating substrate placed on the substrate support by a transfer robot, the calibrating substrate comprises:
a circular body having a top surface and a circumference;
a plurality of first marking features disposed on the top surface of the body; and
at least one edge marking feature disposed on the top surface of the body and extending along a portion of the circumference; and
wherein the plurality of first marking features and the at least one edge marking feature are configured to be detectable relative to the remaining portions of the top surface of the body by an imaging apparatus; and
wherein the imaging apparatus is coupled to the process chamber and connected to a controller, the controller comprising instructions that, when executed, cause:
the imaging apparatus to capture one or more images the calibrating substrate and the substrate support, the one or more images showing a plurality of marking features on the calibrating substrate relative to one or more predefined features on the substrate support, the one or more predefined features being disposed at predetermined locations on the substrate support; and
a processor to determine a true center of the calibrating substrate and a center of the substrate support using the one or more images.

17. The system of claim 16, wherein the controller further comprises instructions that, when executed, cause the processor to determine a difference between the center of the substrate support and the true center of the calibrating substrate and compare the difference to a predetermined threshold limit to determine if an offset correction is needed.

18. The system of claim 17, wherein the controller further comprises instructions that, when executed, cause the processor to adjust a transfer robot based on the offset correction, if the offset correction is determined to be needed.

19. The system of claim 16, wherein the controller further comprises instructions that, when executed, cause the processor to digitally implement in the one or more images the one or more predefined features on the substrate support after the one or more images are captured by the imaging apparatus.

20. The system of claim 16, wherein the controller further comprises instructions that, when executed, cause:
the substrate support to rotate the calibrating substrate;
the imaging apparatus to capture one or more images of the calibrating substrate and the substrate support as the calibrating substrate is rotated; and
the processor to monitor a gap offset between the calibrating substrate and the substrate support using the at least one edge marking feature on the calibrating substrate and the one or more images of the calibrating substrate being rotated by the substrate support.
